(19) United States
(12) Patent Application Publication
(10) Pub. No.: US 2011/0267898 A1
(43) Pub. Date: Nov. 3, 2011

(54) SEMICONDUCTOR MEMORY APPARATUS

(75) Inventors: Tae Sik Yun, Ichon-shi (KR); Young Jun Ku, Ichon-shi (KR)

(73) Assignee: Hynix Semiconductor Inc., Ichon-shi (KR)

(21) Appl. No.: 12/841,053

(22) Filed: Jul. 21, 2010

(30) Foreign Application Priority Data
Apr. 30, 2010 (KR) 10-2010-0040663

(51) Int. Cl. G11C 7/10

(52) U.S. Cl. 365/189.05; 365/193

(57) ABSTRACT

A semiconductor memory apparatus includes a clock transmission unit configured to selectively output a data strobe clock signal or a phase correction clock signal based on an operation mode, and a data latch unit configured to latch a plurality of data signals under a control of a clock signal which is outputted from the clock transmission unit.

### CROSS-REFERENCES TO RELATED APPLICATION

The present application claims priority under 35 U.S.C. §119(a) to Korean Application No. 10-2010-0040663, filed on Apr. 30, 2010, in the Korean Intellectual Property Office, which is incorporated herein by reference in its entirety as if set forth in full.

### BACKGROUND

1. Technical Field

The present invention relates to a semiconductor memory apparatus, and more particularly, to a technology for latching data.

2. Related Art

A semiconductor memory apparatus typically operates based on an externally-supplied clock signal. Since the external clock signal inputted to the semiconductor memory apparatus is delayed inside the memory apparatus, when data is outputted using the delayed clock signal, often the output data are not synchronized with the external clock signal. Therefore, a clock phase correction circuit such as a delay locked loop (DLL) or a phase locked loop (PLL) is typically used to compensate for the timing difference with the external clock signal.

On the other hand, a plurality of data signals sequentially inputted to the semiconductor memory apparatus are latched by a data latch which are in synchronization with a rising edge and a falling edge of a data strobe clock signal, and are transmitted to memory cells through a data transmission line. The data strobe clock signal is generated by buffering an external data strobe clock signal in a data strobe input buffer. For reference, the external data strobe clock signal and the data signals are transmitted to the semiconductor memory apparatus from an external controller and a test device.

Since the test device has a limited number of channels, it is necessary to reduce the number of channels used for one semiconductor memory apparatus in order to test a large number of semiconductor memory apparatuses simultaneously. Accordingly, the semiconductor memory apparatus does not receive the external data strobe clock signal in a test mode, and latches data signals by using a clock signal obtained by buffering the external clock signal in the data latch. The external clock signal is buffered by a clock input buffer and is outputted to the data latch through a clock transmission path as a clock signal. The clock signal transmitted through the clock transmission path is delayed by a predetermined amount and reaches the data latch. Therefore, when the frequency of the clock signal is increased and data signals are transmitted at a high speed, it may not be possible to ensure a sufficient timing margin for the data latch to latch the data signals.

### SUMMARY

In one embodiment of the present invention, a semiconductor memory apparatus includes: a clock transmission unit configured to selectively output a data strobe clock signal or a phase correction clock signal based on an operation mode; and a data latch unit configured to latch a plurality of data signals under the control of a clock signal which is outputted from the clock transmission unit.

In another embodiment of the present invention, a semiconductor memory apparatus includes: a clock phase correction unit configured to receive a clock signal and to output a phase correction clock signal having a phase advanced by a delay amount of a clock transmission path; a clock transmission unit configured to selectively output a data strobe clock signal, which is received through a data strobe transmission path having a delay amount smaller than a delay amount of the clock transmission path, or a phase correction clock signal, which is received through the clock transmission path, based on an operation mode; and a data latch unit configured to latch a plurality of data signals under the control of a clock signal which is outputted from the clock transmission unit.

### BRIEF DESCRIPTION OF THE DRAWINGS

Features, aspects, and embodiments are described in conjunction with the attached drawings, in which:

FIG. 1 is a conceptual diagram of a semiconductor memory apparatus according to one embodiment; and

FIG. 2 is a configuration diagram of a clock transmission unit of FIG. 1 according to one embodiment.

### DETAILED DESCRIPTION

A semiconductor memory apparatus according to the present invention is described below with reference to the accompanying drawings through exemplary embodiments.

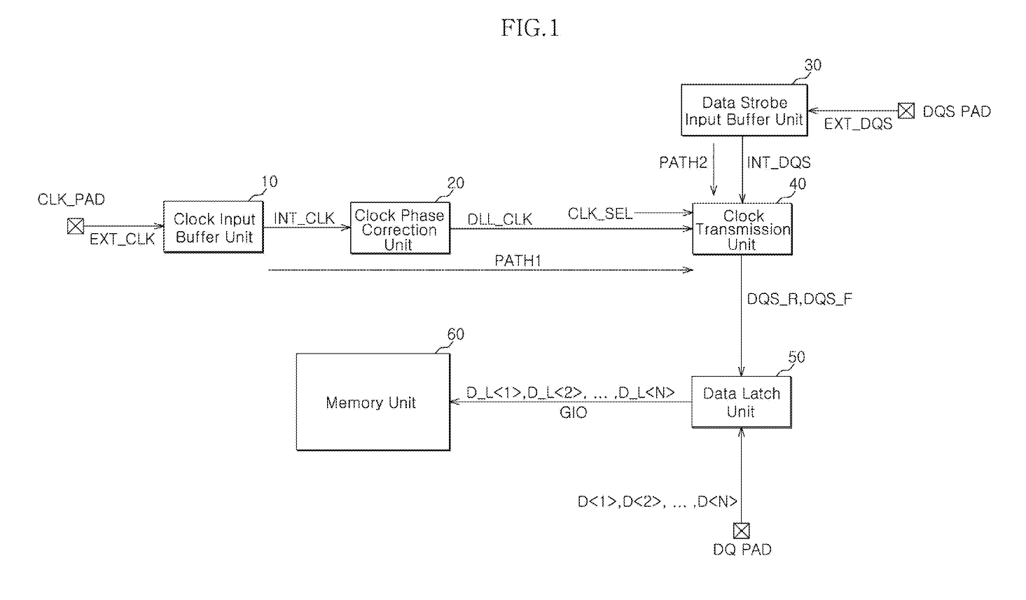

FIG. 1 is a conceptual diagram of the semiconductor memory apparatus according to one embodiment.

The semiconductor memory apparatus according to the embodiment is simplified in order to clearly describe the technical principles of the invention.

Referring to FIG. 1, the semiconductor memory apparatus includes a clock input buffer unit 10, a clock phase correction unit 20, a data strobe input buffer unit 30, a clock transmission unit 40, a data latch unit 50, and a memory unit 60. In the embodiment, the clock phase correction unit 20 includes a delay locked loop (DLL). However, the clock phase correction unit 20 may include a phase locked loop (PLL) according to another embodiment.

The detailed configuration and principal operations of the semiconductor memory apparatus configured as described above are described below.

The clock input buffer unit 10 is configured to buffer an external clock signal EXT_CLK applied through a clock pad CLK_PAD, and output a clock signal INT_CLK.

The clock phase correction unit 20 is configured to receive the clock signal INT_CLK and output a phase correction clock signal DLL_CLK having a phase advanced by the delay amount of a clock transmission path PATH1. In this embodiment, since the clock phase correction unit 20 includes a delay locked loop (DLL), the phase correction clock signal DLL_CLK has a phase advanced by the modeled delay amount of the clock transmission path PATH1. Thus, the phase of the phase correction clock signal DLL_CLK transmitted through the clock transmission path PATH1 substantially coincides with the phase of the external clock signal EXT_CLK, even if the phase correction clock signal DLL_CLK is delayed by a transmission line, a buffer, a repeater or the like of the clock transmission path PATH1. Although not shown in FIG. 1, since a data output unit of the semiconductor memory apparatus is configured to output data signals externally under the control of the phase correction clock signal DLL_CLK, the data signals outputted externally may be precisely synchronized with the external clock signal EXT_CLK.

The data strobe input buffer unit 30 is configured to buffer an external data strobe clock signal EXT_DQS applied through a data strobe pad DQS PAD and to output a data strobe clock signal INT_DQS. The external data strobe clock signal EXT_DQS is transmitted to the semiconductor memory apparatus from an external controller or test device.

The clock transmission unit 40 is configured to selectively output the data strobe clock signal INT_DQS, which is received through a data strobe transmission path PATH2 having a delay amount smaller than that of the clock transmission path PATH1, or the phase correction clock signal DLL_CLK, which is received through the clock transmission path PATH1, based on the operation mode. The clock transmission unit 40 is configured to output the data strobe clock signal INT_DQS in a normal mode, and to output the phase correction clock signal DLL_CLK in a test mode.

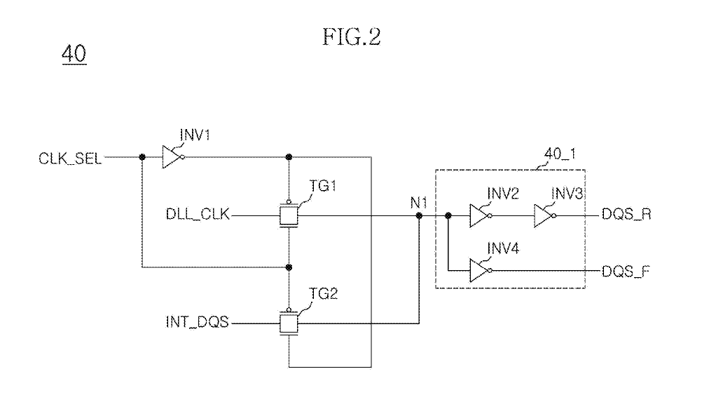

FIG. 2 is a configuration diagram of the clock transmission unit of FIG. 1 according to the embodiment.

Referring to FIG. 2, the clock transmission unit 40 includes a first switching section TG1, a second switching section TG2, and a clock driving section 40_1.

The first switching section TG1 is configured to output the phase correction clock signal DLL_CLK to the output terminal N1 under the control of the clock selection signal CLK_SEL. The second switching section TG2 is configured to output the data strobe clock signal INT_DQS to an output terminal N1 under the control of a clock selection signal CLK_SEL. The clock driving section 40_1 is configured to drive the clock signal, which is outputted to the output terminal N1, as a data clock signal DQS_R and a data clock bar signal DQS_F. One of the first switching section TG1 and the second switching section TG2 is selectively turned on under the control of the clock selection signal CLK_SEL. In this embodiment, the switching section includes a transmission gate. The clock selection signal CLK_SEL substantially maintains a low level in a normal mode, substantially maintains a high level in a test mode, and is outputted from a control circuit such as a command processing unit. The clock transmission unit 40 is configured to drive the data strobe clock signal INT_DQS as the data clock signal DQS_R and the data clock bar signal DQS_F in the normal mode, and drive the phase correction clock signal DLL_CLK as the data clock signal DQS_R and the data clock bar signal DQS_F in the test mode.

The data latch unit 50 is configured to latch a plurality of data signals D<1>, D<2>, . . . , D<N> under the control of the data clock signal DQS_R and the data clock bar signal DQS_F, which are outputted from the clock transmission unit 40. The data latch unit 50 is configured to latch the plurality of sequentially applied data signals D<1>, D<2>, . . . , D<N> under the control of the data clock signal DQS_R and the data clock bar signal DQS_F, which are outputted from the clock transmission unit 40, and to output a plurality of data signals D_L<1>, D_L<2>, . . . , D_L<N>, which are latched after all the plurality of data signals D<1>, D<2>, . . . , D<N> are latched, to a data transmission line GIO. The data signals D_L<1>, D_L<2>, . . . , D_L<N> transmitted through the data transmission line GIO are transmitted to the memory unit 60 and stored in a plurality of memory cells thereof.

In the normal mode, the data latch unit 50 is configured to latch the plurality of data signals D<1>, D<2>, . . . , D<N> under the control of the data clock signal DQS_R and the data clock bar signal DQS_F which correspond to the data strobe clock signal INT_DQS. In the test mode, the data latch unit 50 is configured to latch the plurality of data signals D<1>, D<2>, . . . , D<N> under the control of the data clock signal DQS_R and the data clock bar signal DQS_F, which correspond to the phase correction clock signal DLL_CLK.

For reference, the external clock signal EXT_CLK, the external data strobe clock signal EXT_DQS, and the plurality of data signals D<1>, D<2>, . . . , D<N> are transmitted to the semiconductor memory apparatus from an external controller or a test device. In the normal mode, they are transmitted from an external controller. In the test mode, they are transmitted from a test device.

Consequently, the external clock signal EXT_CLK, the external data strobe clock signal EXT_DQS, and the plurality of data signals D<1>, D<2>, . . . , D<N> are synchronized precisely with one another and inputted to the semiconductor memory apparatus. In general, the external clock signal EXT_CLK is used as a reference signal for controlling the semiconductor memory apparatus, and the external data strobe clock signal EXT_DQS is used as a reference signal for inputting data signals. The rising and falling times of the external clock signal EXT_CLK are the same as those of the external data strobe clock signal EXT_DQS.

The phase correction clock signal DLL_CLK outputted from the delay locked loop (DLL) is generated to have a phase that is same as that of the external clock signal EXT_CLK and the external data strobe clock signal EXT_DQS. Therefore, when external data strobe clock signal EXT_DQS is not received in order to reduce the number of channels used in the test mode, sufficient timing margin may be ensured for the data latch unit to latch data by latching a plurality of applied data signals by using the phase correction clock signal DLL_CLK, even if the data signals are inputted at a high speed.

Consequently, when testing the semiconductor memory apparatus configured as mentioned above through a test device, since the number of channels may be reduced, it may be possible to test a large number of semiconductor memory apparatuses simultaneously and to facilitate testing by transmitting data at a high speed.

In the semiconductor memory apparatus according to the embodiment, the number of channels used in the test mode may be reduced. Furthermore, data signals are latched using a phase correction clock signal in the test mode, so that sufficient timing margin may be ensured for latching data signals inputted at a high speed.

Some embodiment of the present invention have been described above in detail. For reference, embodiments including additional component elements not directly associated with the technical principle of the present invention may be available. Moreover, the specific configurations may vary from one embodiment to another. Since the variations among potential embodiments are too numerous to mention, and can, at any rate, be easily inferred by those skilled in the art, they will not be enumerated herein.

While certain embodiments have been described above, those skilled in the art will understand that the embodiments described are only examples. Accordingly, the semiconductor memory apparatus described herein are not limited by the described embodiments. Rather, the semiconductor memory apparatus described herein are limited only by the claims that follow when taken in conjunction with the above description and accompanying drawings.

What is claimed is:

1. A semiconductor memory apparatus comprising:
a clock transmission unit configured to selectively output a data strobe clock signal or a phase correction clock signal based on an operation mode; and
a data latch unit configured to latch a data signal under control of a clock signal which is outputted from the clock transmission unit.

2. The semiconductor memory apparatus according to claim 1, wherein the clock transmission unit is configured to output the data strobe clock signal in a normal mode or the phase correction clock signal in a test mode.

3. The semiconductor memory apparatus according to claim 1, wherein the data strobe clock signal is provided from the outside.

4. The semiconductor memory apparatus according to claim 3, wherein the phase correction clock signal is generated by a delay locked loop.

5. The semiconductor memory apparatus according to claim 3, wherein the phase correction clock signal is generated by a phase locked loop.

6. The semiconductor memory apparatus according to claim 1, wherein the clock transmission unit comprises:
a first switching section configured to output the data strobe clock signal to an output terminal under control of a clock selection signal;
a second switching section configured to output the phase correction clock signal to the output terminal under control of the clock selection signal; and
a clock driving section configured to drive the clock signal, outputted to the output terminal as a data clock signal and a data clock bar signal; and
wherein one of the first switching section and the second switching section is selectively turned on under control of the clock selection signal.

7. The semiconductor memory apparatus according to claim 1, wherein the data latch unit is configured to latch a plurality of sequentially applied data signals under control of a clock signal outputted from the clock transmission unit, and to output the plurality of data signals to a data transmission line after all of the plurality of data signals are lached.

8. A semiconductor memory apparatus comprising:
a clock phase correction unit configured to receive a clock signal and to output a phase correction clock signal having a phase advanced by a delay amount of a clock transmission path;
a clock transmission unit configured to selectively output a data strobe clock signal, which is received through a data strobe transmission path having a delay amount smaller than a delay amount of the clock transmission path, or the phase correction clock signal, which is received through the clock transmission path, based on an operation mode; and
a data latch unit configured to latch a data signal under control of a clock signal which is outputted from the clock transmission unit.

9. The semiconductor memory apparatus according to claim 8, further comprising:
a clock input buffer unit configured to buffer an external clock signal and to output the clock signal; and
a data strobe input buffer unit configured to buffer an external data strobe clock signal and to output the data strobe clock signal.

10. The semiconductor memory apparatus according to claim 8, wherein the clock transmission unit is configured to output the data strobe clock signal in a normal mode and to output the phase correction clock signal in a test mode.

11. The semiconductor memory apparatus according to claim 8, wherein the clock phase correction unit includes a delay locked loop.

12. The semiconductor memory apparatus according to claim 8, wherein the clock phase correction unit includes a phase locked loop.

13. The semiconductor memory apparatus according to claim 8, wherein the clock transmission unit comprises:
a first switching section configured to output the data strobe clock signal to an output terminal under control of a clock selection signal;
a second switching section configured to output the phase correction clock signal to the output terminal under control of the clock selection signal; and
a clock driving section configured to drive the clock signal outputted to the output terminal as a data clock signal and a data clock bar signal; and
wherein one of the first switching section and the second switching section is selectively turned on under control of the clock selection signal.

14. The semiconductor memory apparatus according to claim 8, wherein the data latch unit is configured to latch a plurality of sequentially applied data signals under control of a clock signal outputted from the clock transmission unit, and to output the plurality of data signals, which are latched after all of the plurality of data signals are latched, to a data transmission line.
